(19) United States
(12) Patent Application Publication
(10) Pub. No.: US 2026/0149411 A1
(43) Pub. Date: May 28, 2026

(54) DOHERTY POWER AMPLIFIER MODULE WITH 90/180 OUTPUT COMBINING CIRCUIT AND OUTPUT HARMONIC TERMINATION CIRCUIT

(71) Applicant: NXP USA, Inc., AUSTIN, TX (US)

(72) Inventors: Xin Fu, Chandler, AZ (US); Jeffrey Spencer Roberts, Tempe, AZ (US); Lu Wang, Chandler, AZ (US)

(21) Appl. No.: 18/956,576

(22) Filed: Nov. 22, 2024

(51) Int. Cl. H03F 1/02; H03F 1/56; H03F 3/24; H03F 3/60

(52) U.S. Cl. CPC H03F 1/0288; H03F 1/565; H03F 3/245; H03F 3/602; H03F 2200/423; H03F 2200/451

(57) ABSTRACT

An amplifier module includes carrier and peaking amplifier dies and an output combining circuit coupled to a module substrate. The output combining circuit includes carrier and peaking output circuits coupled between the carrier and peaking amplifier dies and a combining node. The carrier output circuit includes a harmonic termination circuit and a first transmission line coupled between the carrier amplifier die and the combining node. The peaking output circuit includes a second transmission line and a third transmission line coupled in series between the peaking amplifier die and the combining node, an intermediate node between the second and third transmission lines, and a first capacitor coupled between the intermediate node and the ground reference node. The combining node is configured to combine amplified carrier and peaking output signals produced by the carrier and peaking amplifier dies and conveyed through the carrier and peaking output circuits, respectively.

### TECHNICAL FIELD

Embodiments of the subject matter described herein generally relate to Doherty power amplifiers.

### BACKGROUND

For many years, the Doherty power amplifier has been one of the most popular amplifiers for cellular infrastructure applications, given its ability to provide efficient and linear amplification of high peak-to-average power ratio (PAPR) signals. A well-designed, conventional Doherty power amplifier exhibits linear signal amplification across a range of average output power levels, with high efficiency amplification being achievable in the high power region of operation.

To achieve high-efficiency operation, attempts are made to design Doherty power amplifiers so that power dissipated within the amplifier is minimized. A well-designed Doherty power amplifier is configured to most efficiently amplify radio frequency (RF) signals that have their signal energy centered around a particular fundamental frequency of operation. Due to non-linearities and impedance mismatches within the amplifier, however, signal energy at harmonic frequencies (e.g., second and higher order harmonic frequencies) may be added into an RF signal that is being amplified by a Doherty power amplifier. The presence of the harmonic signal energy may degrade the efficiency and linearity of the Doherty power amplifier. Therefore, some Doherty power amplifier designs include harmonic termination circuits at the inputs and/or outputs of the carrier and peaking amplifiers.

A challenge that persists is that, in some types of Doherty power amplifiers, harmonic termination circuitry at the input and/or output of the carrier and peaking amplifiers may undesirably limit the bandwidth of the amplifier. Specifically, the dispersive nature of the backed-off power load impedance (Zmod) at the fundamental frequency of operation for some Doherty power amplifiers (e.g., 90/0 Doherty power amplifiers) may discourage the inclusion of conventional harmonic frequency resonance circuits in such amplifiers. However, the absence of harmonic termination circuitry limits performance of a Doherty power amplifier. Accordingly, what are needed are Doherty power amplifier designs that provide good harmonic frequency terminations without unduly limiting the bandwidth of the amplifier.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a schematic drawing of a Doherty power amplifier, in accordance with an example embodiment;

FIG. 2 is a top view of a Doherty power amplifier module that embodies the Doherty power amplifier of FIG. 1, in accordance with an example embodiment;

FIG. 3 is a top view of a portion of an amplifier system that includes the Doherty power amplifier module of FIG. 2, in accordance with an example embodiment;

FIG. 4 is a graph illustrating power efficiency curves for a conventional 90/0 Doherty power amplifier and for an embodiment of a 90/180 Doherty power amplifier; and

FIG. 5 is a Smith chart illustrating efficiency spread for a conventional Doherty power amplifier and for an embodiment of a Doherty power amplifier.

### DETAILED DESCRIPTION

Embodiments of 90/180 Doherty power amplifiers are disclosed herein, which are characterized by highly efficient operation across a wider bandwidth than is typically possible with conventional 90/0 Doherty power amplifiers. More specifically, embodiments of 90/180 Doherty power amplifiers disclosed herein exhibit higher efficiency across a band due to the wide bandwidth brought by the 90/180 topology. This allows the inclusion of harmonic termination circuitry at the output of (at least) the carrier amplifier, which may result in improved efficiency across the band with little roll-off, when compared to a 90/0 Doherty power amplifier. Further, for the amplifier embodiments discussed herein, the harmonic termination circuitry does not unduly limit the bandwidth of the amplifier.

Further still, embodiments of physical implementations of 90/180 Doherty power amplifiers are described herein. Specifically, 90/180 Doherty power amplifier modules are described, in which the amplifier circuit components are arranged and oriented in a manner that enables more compact amplifier modules, when compared with amplifiers that are implemented on a circuit board using discrete components, and when compared with amplifier modules that have conventionally-arranged circuit components. As will be described in more detail below, some of the compactness improvements are achieved by moving certain amplifier components (e.g., baseband decoupling resistors and capacitors) outside of the module package and onto a system substrate. Moving these amplifier components outside of the module package also results in a lower bill of materials (BoM) for the amplifier module embodiments.

Essentially, embodiments of the inventive subject matter take advantage of the efficiency benefits of a 90/180 Doherty power amplifier with harmonic termination circuitry, while keeping the amplifier footprint compact. For example, embodiments of Doherty power amplifiers described herein may exhibit efficiency improvements of several percentage points, compared with conventional 90/0 Doherty power amplifiers, while being implementable in modules that are approximately the same size as a conventional 90/0 Doherty power amplifier module.

As used herein, the term “90/180 Doherty power amplifier” is meant to differentiate the Doherty amplifier embodiments disclosed herein from other types of Doherty power amplifiers. Generally, the term “90/180” refers to electrical lengths (at a fundamental frequency of operation) between carrier and peaking amplifier outputs, respectively, and the combining node of a Doherty power amplifier. The “90” in “90/180” refers to the approximate electrical length (in degrees) of a conductive path between the output of the carrier amplifier and the combining node at the fundamental frequency. Similarly, the “180” in “90/180” refers to the approximate electrical length of a conductive path between the output of the peaking amplifier and the combining node.

It should be understood that, even though amplifier embodiments disclosed herein may be referred to as “90/180 Doherty power amplifiers,” those amplifier embodiments may be characterized by slightly smaller electrical lengths than exactly 90 degrees or exactly 180 degrees between the carrier and peaking amplifiers, respectively, and the combining node. For example, in some embodiments, the electrical length between the carrier amplifier output and the combining node may be in a range of about 60 degrees to about 90 degrees, and the electrical length between the peaking amplifier output and the combining node may be in a range of about 140 degrees to about 180 degrees. Accordingly, use of the term “90/180 Doherty power amplifier” is not meant to limit the scope of the inventive subject matter to amplifiers that have electrical lengths of exactly 90 degrees and exactly 180 degrees between the carrier and peaking amplifier outputs, respectively, and the combining node. Instead, “90/180 Doherty power amplifier” includes amplifiers that have electrical lengths of approximately 90 degrees and approximately 180 degrees between the carrier and peaking amplifier outputs, respectively, and the combining node, where “approximately x degrees” refers to a range of values with lower and upper bounds that occur about +/- 20 degrees on either side of x.

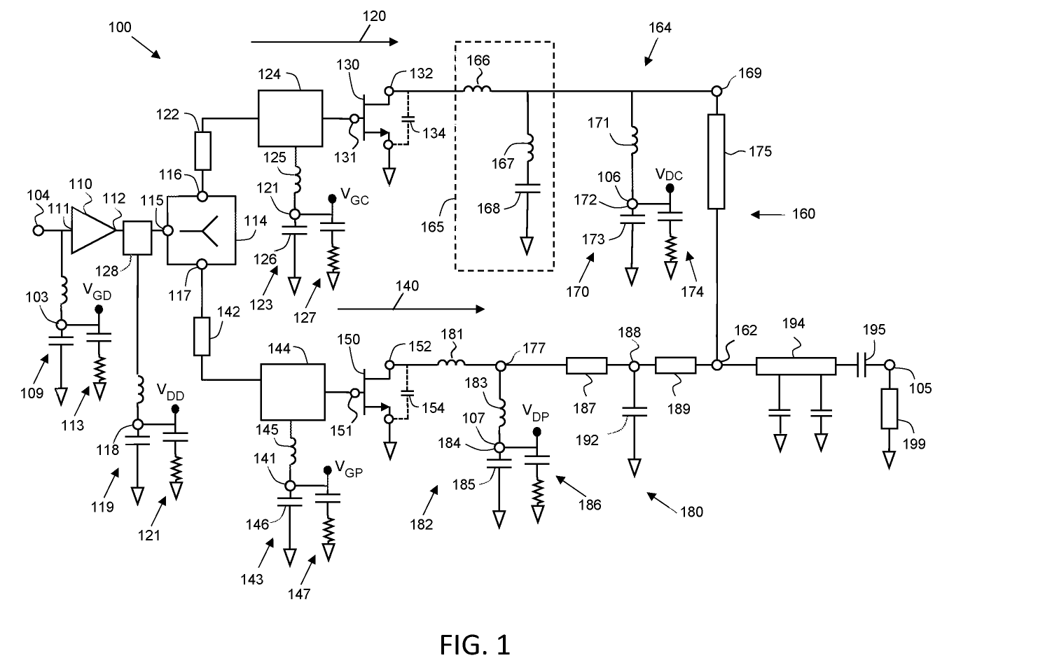

FIG. 1 is a schematic drawing of a Doherty power amplifier 100, in accordance with an example embodiment. As will be described in detail below, Doherty power amplifier 100 includes various circuits that are electrically coupled between the RF input 104 and the RF output 105. It may be noted here that the term “circuit,” as used herein, is analogous to “electronic circuit”, “circuitry,” and “network.”

More specifically, Doherty power amplifier 100 includes an RF input 104, an RF output 105, a driver amplifier 110, a power splitter 114, a carrier amplification path 120 with a carrier amplifier 130, a peaking amplification path 140 with a peaking amplifier 150, an output combining circuit 160 with a combining node 162, and an output impedance transformer 194. When incorporated into a larger electronic system (e.g., a transmitter of a cellular communication system), the RF input 104 is electrically coupled to an RF signal source, and the RF output 105 is electrically coupled to an antenna (or other type of load, not illustrated).

Doherty power amplifier 100 is considered to be a “two-way” Doherty power amplifier, which includes one carrier amplification path 120 and one peaking amplification path 140. Essentially, during operation of Doherty power amplifier 100, the carrier amplifier 130 provides RF signal amplification along the carrier amplification path 120, and the peaking amplifier 150 provides RF signal amplification along the peaking amplification path 140. The amplified carrier and peaking RF signals are then conveyed through the output combining circuit 160 and combined at combining node 162 before provision through the output impedance transformer 194 to the RF output 105. To ensure proper Doherty amplifier operation, the carrier amplifier 130 is biased to operate in class AB mode or deep class AB mode, and the peaking amplifier 150 is biased to operate in class C mode or deep class C mode. In some configurations, the peaking amplifier 150 may be biased to operate in class B or class J mode.

The driver amplifier 110 may be implemented as a power transistor. Accordingly, the driver amplifier 110 may have a control terminal 111 (e.g., a gate terminal) coupled to the RF input 104, a first current-carrying terminal 112 (e.g., a drain or output terminal), and a second current-carrying terminal (e.g., a source terminal, not numbered). The control terminal 111 functions as an input to the driver amplifier 110, and thus may be referred to herein as a driver amplifier input terminal 111. The driver amplifier input terminal 111 is configured to receive the input RF signal from RF input 104. The driver amplifier 110 is further configured to amplify the received input RF signal, and to produce an amplified RF signal at the driver amplifier output terminal 112.

A shunt inductor-capacitor (LC) circuit 109 is coupled between the driver amplifier control terminal 111 and a ground reference node. According to one or more embodiments, the shunt LC circuit 109 includes an inductive element (not numbered) and a capacitor (not numbered) coupled in series, with an intermediate node between the inductive element and the capacitor. For example, the inductive element may have an inductance value in a range of about 0.3 nanohenries (nH) to about 1.0 nH, and the capacitor may have a capacitance value in a range of about 8.0 picofarads (pF) to about 20.0 pF, although the inductance and/or capacitance values may be lower or higher, as well.

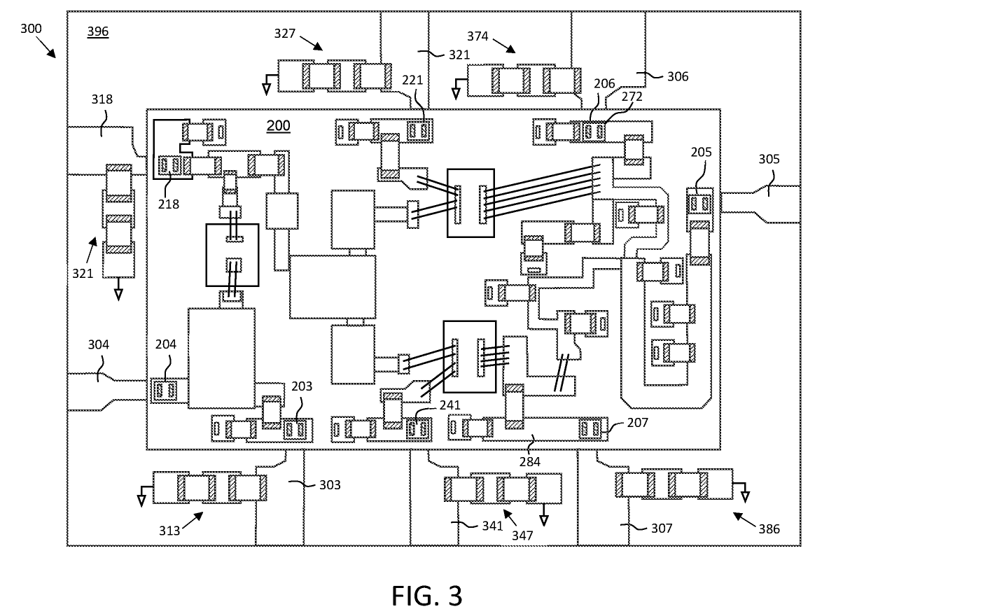

According to one or more embodiments, the intermediate node corresponds to a driver gate bias voltage terminal 103, which may correspond to an “RF cold point” in amplifier 100. An RF cold point (e.g., the intermediate node and driver gate bias voltage terminal 103) represents a low impedance point in the circuit for RF signals, and thus is a good point for provision of a gate bias voltage, V_{GD}, for the driver amplifier 110. Accordingly, as shown in FIG. 1, a driver gate bias circuit 113 is coupled to the intermediate node/driver gate bias terminal 103. According to one or more embodiments, and as described in more detail in conjunction with FIG. 3, the driver gate bias circuit 113 may include a shunt capacitor (not numbered) and resistor (not numbered) coupled in series between the intermediate node/driver gate bias terminal 103 and a ground reference node.

Another shunt LC circuit 119 is coupled between the driver amplifier output terminal 112 and a ground reference node. According to one or more embodiments, the shunt LC circuit 119 includes an inductive element (not numbered) and a capacitor (not numbered) coupled in series, with an intermediate node between the inductive element and the capacitor. For example, the inductive element may have an inductance value in a range of about 0.7 nH to about 2.0 nH, and the capacitor may have a capacitance value in a range of about 8.0 pF to about 30.0 pF, although the inductance and/or capacitance values may be lower or higher, as well.

According to one or more embodiments, the intermediate node corresponds to a driver drain bias voltage terminal 118, which may correspond to another RF cold point in amplifier 100, and thus is a good point for provision of a drain bias voltage, V_{DD}, for the driver amplifier 110. Accordingly, as shown in FIG. 1, a driver drain bias circuit 121 is coupled to the intermediate node/driver drain bias terminal 118. According to one or more embodiments, and as described in more detail in conjunction with FIG. 3, the drain gate bias circuit 121 may include a shunt capacitor (not numbered) and resistor (not numbered) coupled in series between the intermediate node/driver drain bias terminal 118 and a ground reference node.

According to one or more embodiments, an impedance matching circuit 128 may be coupled between the driver amplifier output terminal 112 and the power splitter 114. The power splitter 114 has a power splitter input 115, a first power splitter output 116, and a second power splitter output 117. The power splitter input 115 is electrically coupled to the driver amplifier output terminal 112, and the power splitter 114 is configured to receive, at power splitter input 115, the amplified RF signal from the driver amplifier 110. The power splitter 114 is further configured to divide the power of the input RF signal into a carrier input RF signal and a peaking input RF signal, which are produced at the first and second power splitter outputs 116, 117, respectively. In this manner, the power splitter 114 is configured to provide a carrier input RF signal to the carrier amplification path 120, and to provide a peaking input RF signal to the peaking amplification path 140.

Power splitter 114 divides the power of the amplified RF signal according to a carrier-to-peaking size ratio. For example, when Doherty power amplifier 100 has a symmetric Doherty power amplifier configuration in which the carrier amplifier 130 and the peaking amplifier 150 are substantially equal in size, the power splitter 114 may divide the power such that about half of the input signal power is provided to the carrier amplification path 120, and about half of the input signal power is provided to the peaking amplification path 140. Conversely, when Doherty power amplifier 100 has an asymmetric Doherty power amplifier configuration, the power splitter 114 may divide the power unequally. For example, when the Doherty power amplifier 100 has a 2:1 peaking-to-carrier size ratio, the power splitter 114 may divide the input signal power so that approximately one third of the input signal power is provided to the carrier amplification path 120, and approximately two-thirds of the input signal power is provided to the peaking amplification path 140.

Either way, power splitter 114 may have any of a variety of configurations, including a Wilkinson-type splitter, a hybrid quadrature splitter, and so on. Proper operation of a Doherty power amplifier requires the carrier input RF signal to be about 90 degrees out of phase with the peaking input RF signal when those signals arrive at the inputs 131, 151 to the carrier and peaking amplifiers 130, 150, respectively. This 90 degree phase difference is implemented at the input to the Doherty power amplifier in order to compensate for a 90 degree phase shift applied at the output of the Doherty power amplifier (e.g., including a phase shift applied by transmission line 175), as will be discussed later. In some embodiments (e.g., when hybrid quadrature splitters are used), power splitter 114 is configured to produce a peaking input RF signal at the second power splitter output 117 that is about 90 degrees out of phase from (e.g., delayed from) the carrier input RF signal produced at the first power splitter output 116. In other embodiments (e.g., when Wilkinson-type splitters are used), power splitter 114 is configured to produce carrier and peaking input RF signals at the first and second power splitter outputs 116, 117 that are substantially in phase with each other, and the above-mentioned 90 degree phase difference between the carrier and peaking input RF signals may be imparted through one or more phase adjustment circuits 122, 142 (described below) between the power splitter outputs 116, 117 and the carrier and peaking amplifiers 130, 150.

The carrier amplification path 120 is electrically coupled to the first power splitter output 116. The carrier amplification path 120 includes a first phase adjustment circuit 122, a carrier input matching network (IMN) 124, , a shunt LC circuit 123, and the carrier amplifier 130. Similarly, the peaking amplification path 140 is electrically coupled to the second power splitter output 117, and includes a second phase adjustment circuit 142, a peaking IMN 144, , a shunt LC circuit 143, and the peaking amplifier 150.

The first phase adjustment circuit 122 and the carrier IMN 124 (together referred to as a “carrier input circuit”) are coupled between the first power splitter output 116 and the carrier amplifier 130. In some embodiments, the first phase adjustment circuit 122 and the carrier IMN 124 may include distinct and separate circuits. In other embodiments, the first phase adjustment circuit 122, and the carrier IMN 124 may include one or more common circuit elements. Similarly, the second phase adjustment circuit 142 and the peaking IMN 144 (together referred to as a “peaking input circuit”) are coupled between the second power splitter output 117 and the peaking amplifier 150. In some embodiments, the second phase adjustment circuit 142 and the peaking IMN 144 may include distinct and separate circuits. In other embodiments, the second phase adjustment circuit 142, and the peaking IMN 144 may include one or more common circuit elements.

Each of the carrier and peaking IMNs 124, 144 may include, for example, a lowpass or bandpass circuit configured as T- or pi- impedance matching network, although other matching network topologies also are anticipated. However they are configured, the carrier and peaking IMNs 124, 144 are configured to incrementally increase the circuit impedance. Each of the first and second phase adjustment circuits 122, 142 are configured to ensure that the proper phase relationship is established between the carrier and peaking input RF signals when they arrive at the inputs 131, 151 to the carrier and peaking amplifiers 130, 150.

The carrier amplifier 130 and the peaking amplifier 150 are electrically coupled to the carrier and peaking IMNs 124, 144, and each amplifier 130, 150 may be implemented as a power transistor. Accordingly, each of the carrier and peaking amplifiers 130, 150 have a control terminal 131, 151 (e.g., a gate terminal) coupled to the carrier or peaking IMN 124, 144, a first current-carrying terminal 132, 152 (e.g., a drain terminal), and a second current-carrying terminal (e.g., a source terminal, not numbered). The control terminals 131, 151 function as inputs to the carrier and peaking amplifiers 130, 150, and thus may be referred to herein as carrier and peaking amplifier input terminals 132, 152, respectively. The carrier and peaking amplifier input terminals 131, 151 are configured to receive the impedance-adjusted and phase-adjusted carrier and peaking input RF signals, respectively.

The shunt LC circuit 123 is coupled between the carrier amplifier input terminal 131 and a ground reference node. According to one or more embodiments, the shunt LC circuit 123 includes an inductive element 125 and a capacitor 126 coupled in series, with an intermediate node between the inductive element and the capacitor. For example, the inductive element 125 may have an inductance value in a range of about 0.7 nH to about 2.0 nH, and the capacitor 126 may have a capacitance value in a range of about 8.0 pF to about 20.0 pF, although the inductance and/or capacitance values may be lower or higher, as well.

According to one or more embodiments, the intermediate node corresponds to a carrier gate bias voltage terminal 121, which may correspond to another RF cold point in amplifier 100, and thus is a good point for provision of a gate bias voltage, V_{GC}, for the carrier amplifier 130. Accordingly, as shown in FIG. 1, a carrier gate bias circuit 127 is coupled to the intermediate node/carrier gate bias terminal 121. According to one or more embodiments, and as described in more detail in conjunction with FIG. 3, the carrier gate bias circuit 127 may include a shunt capacitor (not numbered) and resistor (not numbered) coupled in series between the intermediate node/carrier gate bias terminal 121 and a ground reference node.

Similarly, the shunt LC circuit 143 is coupled between the peaking amplifier input terminal 151 and a ground reference node. According to one or more embodiments, the shunt LC circuit 143 includes an inductive element 145 and a capacitor 146 coupled in series, with an intermediate node between the inductive element and the capacitor. For example, the inductive element 145 may have an inductance value in a range of about 0.7 nH to about 2.0 nH, and the capacitor 146 may have a capacitance value in a range of about 8.0 pF to about 20.0 pF, although the inductance and/or capacitance values may be lower or higher, as well.

According to one or more embodiments, the intermediate node corresponds to a peaking gate bias voltage terminal 141, which may correspond to another RF cold point in amplifier 100, and thus is a good point for provision of a gate bias voltage, V_{GP}, for the peaking amplifier 150. Accordingly, as shown in FIG. 1, a peaking gate bias circuit 147 is coupled to the intermediate node/peaking gate bias terminal 141. According to one or more embodiments, and as described in more detail in conjunction with FIG. 3, the peaking gate bias circuit 147 may include a shunt capacitor (not numbered) and resistor (not numbered) coupled in series between the intermediate node/peaking gate bias terminal 141 and a ground reference node.

Each of the carrier and peaking amplifiers are configured to amplify the received carrier and peaking input RF signals, and to produce amplified carrier and peaking RF signals at the first current-carrying terminals 132, 152 (e.g., drain terminals), respectively. The first current-carrying terminals 132, 152 function as outputs of the carrier and peaking amplifiers 130, 150, and thus may be referred to herein as carrier and peaking amplifier output terminals 132, 152. The second current-carrying terminals (e.g., the source terminals, not numbered) may be coupled to a ground reference node (represented with a downward-facing triangle in the figures).

According to an embodiment, the carrier and peaking amplifier output terminals 132, 152 each correspond to an intrinsic current generator (e.g., an intrinsic drain) of each of the carrier and peaking amplifiers 130, 150. Capacitances 134, 154 represent parasitic output capacitances (e.g., drain-source capacitances) present at the carrier and peaking amplifier output terminals 132, 152. In other words, the carrier amplifier output terminal 132 is characterized by a drain-source capacitance 134 (or carrier amplifier output capacitance) between the drain and source terminals of the carrier amplifier 130. Similarly, the peaking amplifier output terminal 152 is characterized by a drain-source capacitance 154 (or peaking amplifier output capacitance) between the drain and source terminals of the peaking amplifier 150. It should be understood that capacitances 134, 154 are not discrete physical components (e.g., discrete capacitors), but instead are parasitic capacitances of the carrier and peaking amplifiers 130, 150. According to an embodiment, parasitic capacitances 134, 154 each have a capacitance value in a range of about 0.25 pF to about 20 pF, although the capacitance values may be lower or higher, as well.

An output combining circuit 160 is electrically coupled to the carrier and peaking amplifier output terminals 132, 152. According to one or more embodiments, the output combining circuit 160 includes a combining node 162, a carrier output circuit 164, and a peaking output circuit 180.

The carrier output circuit 164 includes a first transmission path coupled between the carrier amplifier output terminal 132 and the combining node 162. More particularly, according to one or more embodiments, the carrier output circuit 164 includes an output harmonic termination circuit 165, a shunt LC circuit 170, and a first transmission line 175, according to one or more embodiments.

The output harmonic termination circuit 165 is coupled between the carrier amplifier output terminal 132 (or more particularly, the intermediate node 169) and a ground reference node. According to one or more embodiments, the harmonic termination circuit 165 includes a series inducive element 166, an inductive element 167, and a capacitor 168.

The series inductive element 166 includes a first terminal coupled to the carrier amplifier output terminal 132 and a second terminal coupled to an intermediate node 169. According to one or more embodiments, the series inductive element 166 forms a portion of the first transmission path, and contributes to output impedance matching between the carrier amplifier output terminal 132 and the combining node 162. In addition, the series inductive element 166 functions to establish a correct harmonic termination location (together with inductive element 167 and capacitor 168) to ensure high efficiency. The series inductive element 166 may have an inductance value in a range of about 0.5 nH to about 1.5 nH, although the inductance value may be lower or higher, as well.

The inductive element 167 and the capacitor 168 are coupled in series, and are configured to resonate at or near a second harmonic frequency of the fundamental frequency (e.g., where “at or near” means at precisely the second harmonic frequency or at a frequency between about 90 percent and about 105 percent of the second harmonic frequency). For example, the inductive element 167 may have an inductance value in a range of about 0.5 nH to about 1.0 nH, and the capacitor 168 may have a capacitance value in a range of about 0.3 pF to about 0.7 pF, although the inductance and/or capacitance values may be lower or higher, as well.

The shunt LC circuit 170 also is coupled between the carrier amplifier output terminal 132 (or more particularly, the intermediate node 169) and a ground reference node. According to one or more embodiments, the shunt LC circuit 170 includes an inductive element 171 and a capacitor 173 coupled in series, with an intermediate node 172 between the inductive element 171 and the capacitor 173. The shunt LC circuit 170 is configured to adjust the effective output capacitance 134 of the carrier amplifier 130. For example, the inductive element 171 may have an inductance value in a range of about 0.3 nH to about 5.0 nH, and the capacitor 173 may have a capacitance value in a range of about 10 pF to about 30 pF, although the inductance and/or capacitance values may be lower or higher, as well. The inductance value of the inductive element 171 generally depends on the active die gate periphery. The capacitance value of the capacitor 173 functions as an RF short to provide an RF cold point.

According to one or more embodiments, the intermediate node 172 corresponds to a carrier drain bias voltage terminal 106, which may correspond to another RF cold point in amplifier 100, and thus is a good point for provision of a drain bias voltage, V_{DC}, for the carrier amplifier 130. Accordingly, as shown in FIG. 1, a carrier drain bias circuit 174 is coupled to the intermediate node 172/carrier drain bias voltage terminal 106. According to one or more embodiments, and as described in more detail in conjunction with FIG. 3, the carrier drain bias circuit 174 may include a shunt capacitor (not numbered) and resistor (not numbered) coupled in series between the intermediate node 172/carrier drain bias voltage terminal 106 and a ground reference node.

The first transmission line 175 forms another portion of the first transmission path between the carrier amplifier output terminal 132 and the combining node 162 (e.g. the first transmission path includes the first inductive element 166 and the first transmission line 175 coupled in series). The first transmission line 175 has a first end coupled to the intermediate node 169 and a second end coupled to the combining node 162. According to one or more embodiments, the first transmission line 175 is configured to impart a phase delay to the amplified carrier output RF signal produced by the carrier amplifier 130, and also to impart an impedance inversion.

The carrier output circuit 164 is characterized by a first electrical length at the fundamental frequency between the carrier amplifier output terminal 132 and the combining node 162. According to one or more embodiments, the first electrical length (as affected by drain-source capacitance 134) is in a range of about 60 degrees to about 90 degrees at the fundamental frequency.

The peaking output circuit 180 is coupled between the first current-carrying terminal 152 of the peaking amplifier 150 and the combining node 162. The peaking output circuit 180 includes a second transmission path coupled between the peaking amplifier output terminal 152 and the combining node 162. More particularly, according to one or more embodiments, the peaking output circuit 180 includes a series inductive element 181, a shunt LC circuit 182, a second transmission line 187, a third transmission line 189, and a shunt capacitor 192, according to one or more embodiments.

The series inductive element 181 includes a first terminal coupled to the peaking amplifier output terminal 152 and a second terminal coupled to an intermediate node 177. According to one or more embodiments, the series inductive element 181 forms a portion of the second transmission path, and contributes to output impedance matching between the peaking amplifier output terminal 152 and the combining node 162. The series inductive element 181 may have an inductance value in a range of about 0.2 nH to about 0.5 nH, although the inductance value may be lower or higher, as well.

The shunt LC circuit 182 is coupled between the peaking amplifier output terminal 152 (or more specifically, the intermediate node 177) and a ground reference node. According to one or more embodiments, the shunt LC circuit 182 includes an inductive element 183 and a capacitor 185 coupled in series, with an intermediate node 184 between the inductive element 183 and the capacitor 185. The shunt LC circuit 182 is configured to adjust the effective output capacitance 154 of the peaking amplifier 150. For example, the inductive element 183 may have an inductance value in a range of about 1.0 nH to about 5.0 nH, and the capacitor 185 may have a capacitance value in a range of about 10 pF to about 30 pF, although the inductance and/or capacitance values may be lower or higher, as well. Again, the inductance value of the inductive element 183 generally depends on the active die gate periphery, and the capacitance value of the capacitor 185 functions as an RF short to provide an RF cold point.

According to one or more embodiments, the intermediate node 184 corresponds to a peaking drain bias voltage terminal 107, which may correspond to another RF cold point in amplifier 100, and thus is a good point for provision of a drain bias voltage, V_{DP}, for the peaking amplifier 150. Accordingly, as shown in FIG. 1, a peaking drain bias circuit 186 is coupled to the intermediate node 184/peaking drain bias voltage terminal 107. According to one or more embodiments, and as described in more detail in conjunction with FIG. 3, the peaking drain bias circuit 186 may include a shunt capacitor (not numbered) and resistor (not numbered) coupled in series between the intermediate node 184/peaking drain bias voltage terminal 107 and a ground reference node.

The second and third transmission lines 187, 189 form portions of the second transmission path between the peaking amplifier output terminal 152 and the combining node 162 (e.g. the second transmission path includes the second and third transmission lines 187, 189 coupled in series). The second transmission line 187 has a first end coupled to the peaking amplifier output terminal 152 and a second end coupled to an intermediate node 188. The third transmission line 189 has a first end coupled to the intermediate node 188 and a second end coupled to the combining node 162.

According to one or more embodiments, the second transmission line 187 is configured to impart a phase delay and impedance transformation to the amplified peaking output RF signal produced by the peaking amplifier 150, and the third transmission line 189 is configured to impart an additional phase delay and impedance transformation to the amplified peaking output RF signal produced by the peaking amplifier 150. According to one or more embodiments, the electrical length of the second transmission line 187 (and thus the phase delay imparted by line 187) is in a range of about 30 degrees to about 90 degrees at the fundamental frequency. Further, the electrical length of the third transmission line 189 (and thus the phase delay imparted by line 189) is in a range of about 60 degrees to about 120 degrees at the fundamental frequency.

A shunt capacitor 192 is electrically coupled between intermediate node 188 and a ground reference node. The shunt capacitor 192 may, for example, have a capacitance value in a range of about 0.3 pF to about 5.0 pF, although the capacitance value may be lower or higher, as well.

Essentially, the peaking output circuit 180 is characterized by a total (second) electrical length at the fundamental frequency between the peaking amplifier output terminal 152 and the combining node 162. According to one or more embodiments, the second electrical length (including the combined electrical lengths of the second and third transmission lines 187, 189 and as affected by drain-source capacitance 154 and shunt capacitor 192) is in a range of about 140 degrees to about 180 degrees at the fundamental frequency.

The second transmission path between the peaking amplifier output 152 and the combining node 162 is configured in a manner that is more compact in comparison with a conventional Doherty amplifier output circuit. More specifically, by including the shunt capacitor 192 between the second and third transmission lines 187, 189, the physical and electrical length of the second and third transmission lines 187, 189 may be shorter than would be required with a single transmission line (with no shunt capacitance). Thus, the peaking output circuit 180 may be more compact than a conventional peaking output circuit.

Importantly, the total electrical length of the peaking amplifier path 140/peaking output circuit 180 (including the electrical length of the peaking input circuit and any delay imparted by power splitter 114) and the total electrical length of the carrier amplifier path 120/carrier output circuit 164 (including the electrical length of the carrier input circuit) are substantially equal to ensure that the amplified peaking and carrier signals combine in phase at the combining node 162.

The combining node 162 is coupled to the carrier and peaking output circuits 164, 180. The combining node 162 is configured to receive the amplified carrier output signal from the carrier output circuit 164, to receive the amplified peaking signal from the peaking output circuit 180, and to combine the amplified carrier output signal with the amplified peaking output signal. As discussed above, the carrier and peaking amplifier paths 120, 140 and the carrier and peaking output circuits 164, 180 are configured so that the amplified carrier and peaking output signals arrive in phase (and thus are combined in phase) at the combining node 162.

The output impedance transformer 194 is electrically coupled between the combining node 162 and the RF output 105. The output impedance transformer 194 is configured to modify the impedance at the combining node 162. According to an embodiment, the output impedance transformer 194 may include a fourth transmission line and a plurality of shunt capacitors (not numbered).

A DC blocking capacitor 195 also may be coupled between the combining node 162 and the RF output 105. As indicated above, the RF output 105 may be coupled to a load 199 (e.g., an antenna or other type of load).

Along with the circuitry illustrated in FIG. 1, Doherty power amplifier 100 may include additional circuitry, as well. For example, although not illustrated in FIG. 1, Doherty power amplifier 100 may include various additional DC bias circuits coupled to the inputs of the carrier and peaking amplifiers 130, 150. In addition, Doherty power amplifier 100 may include video bandwidth circuits and/or other circuits that will ensure proper operation of and/or improve the performance of the Doherty power amplifier 100.

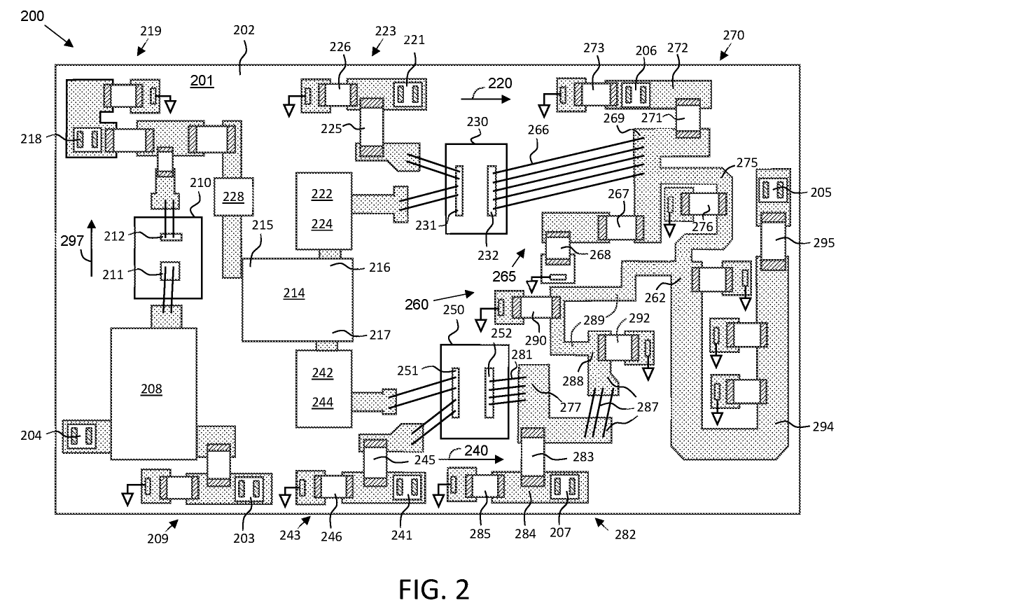

FIG. 2 is a top view of a Doherty power amplifier module 200 that embodies the Doherty power amplifier 100 of FIG. 1, in accordance with an example embodiment. For enhanced understanding, the reference numbers for corresponding components of the amplifier 100 in FIG. 1 and the physical module 200 in FIG. 2 have the same last two digits (e.g., carrier amplifier 130, FIG. 1, and carrier amplifier die 230, FIG. 2, are corresponding components). For conciseness, all of the details of various circuits and components discussed above in conjunction with FIG. 1 are not repeated in the description of FIG. 2, but those details are intended to apply to the corresponding circuits and components discussed below in conjunction with FIG. 2.

Doherty power amplifier module 200 is a surface-mountable device, which includes a module substrate 201 with a mounting surface 202 and an opposite bottom surface (not illustrated or numbered). The module substrate 201 may include, for example, a printed circuit board (PCB) that includes multiple patterned conductive layers interleaved with one or more dielectric layers.

According to one or more embodiments, the bottom surface of the module substrate 201 is configured to be connected to a surface of a separate system substrate (e.g., substrate 396, FIG. 3). More particularly, ends of various signal and voltage terminals (discussed below) that are exposed at the bottom surface of the module substrate 201 may be physically and electrically coupled (e.g., using solder or conductive adhesive) to corresponding conductive pads and traces at a top surface of the separate system substrate in order to surface mount the module 200 to the system substrate. Additionally, a patterned conductive layer (not illustrated) on the bottom surface of the module substrate 201 may function as a ground reference node for the module 200, and the patterned conductive layer may be physically and electrically coupled to ground pads at the top surface of the separate system substrate.

In some embodiments, the module substrate 201 may include thermally conductive structures (e.g., conductive coins and/or thermal vias), which extend between the mounting and bottom surfaces of the module substrate 201, and to which heat-producing dies (e.g., dies 230, 250) may be coupled. Portions of the thermally conductive structures at the bottom surface of the module substrate 201 may be coupled to thermally conductive structures of the separate system substrate to enable the heat to be conveyed, ultimately, to heat sinks that can dissipate the die-produced heat.

A plurality of signal and voltage-conveying terminals extend through the module substrate 201. According to one or more embodiments, each of these terminals may include aligned conductive pads on the mounting and bottom surfaces of the module substrate 201, and one or more conductive structures (e.g., conductive vias) that extend between the aligned conductive pads (i.e., between the mounting surface 202 and the bottom surface of the module substrate 201). In other embodiments, other types of terminals may be used.

According to one or more embodiments, the plurality of terminals may include an RF input terminal 204 (corresponding to RF input 104, FIG. 1), an RF output terminal 205 (corresponding to RF output 105, FIG. 1), a driver gate bias voltage terminal 203 (corresponding to driver gate bias voltage terminal 103), a driver drain bias voltage terminal 218 (corresponding to driver drain bias voltage terminal 118), a carrier gate bias voltage terminal 221 (corresponding to carrier gate bias voltage terminal 121), a peaking gate bias voltage terminal 241 (corresponding to peaking gate bias voltage terminal 141), a carrier drain bias voltage terminal 206 (corresponding to carrier drain bias voltage terminal 106), and a peaking drain bias voltage terminal 207 (corresponding to peaking drain bias voltage terminal 107). The plurality of terminals also may include additional terminals (not illustrated).

Referring briefly to FIG. 3, when module 200 is incorporated into a larger electronic system (e.g., a transmitter of a cellular communication system), the RF input terminal 204 may be physically and electrically coupled to a first trace 304 that is exposed at a mounting surface 302 of a system substrate 396, the RF output terminal 205 may be physically and electrically coupled to a second trace 305 at the mounting surface 302, the driver gate and drain bias voltage terminals 203, 218 may be physically and electrically coupled to third and fourth traces 303, 318 at the mounting surface 302, the carrier and peaking gate bias voltage terminals 221, 241 may be physically and electrically coupled to fifth and sixth traces 321, 341 at the mounting surface 302, and the carrier and peaking drain bias voltage terminals 206, 207 may be physically and electrically coupled to seventh and eighth traces 306, 307 at the mounting surface 302.

The Doherty power amplifier module 200 also includes a driver amplifier die 210 (e.g., driver amplifier 110, FIG. 1), a power splitter 214 (e.g., power splitter 114, FIG. 1), a carrier amplification path 220 (e.g., path 120, FIG. 1) with a carrier amplifier die 230 (e.g., carrier amplifier 130, FIG. 1), a peaking amplification path 240 (e.g., path 140, FIG. 1) with a peaking amplifier die 250 (e.g., peaking amplifier 150, FIG. 1), an output combining circuit 260 (e.g., circuit 160, FIG. 1) with a combining node 262 (e.g., combining node 162, FIG. 1), and an output impedance transformer 294 (e.g., transformer 194, FIG. 1).

The mounting surface 202 of the module substrate 201 is configured to support various semiconductor dies (e.g., dies 210, 230, 250) and surface mount components coupled thereto. More particularly, the various dies 210, 230, 250 are physically coupled to the mounting surface 202 of the module substrate 201. For example, bottom surfaces of each of the dies 210, 230, 250 may be coupled to surfaces of the above-described thermally conductive structures that extend between the mounting and bottom surfaces of the module substrate 201. This enables heat produced by the dies 210, 230, 250 to be conveyed from the dies 210, 230, 250 through the thermally conductive structures to the bottom surface of the module substrate 201. The terminals of other surface mount components may be physically and electrically coupled to conductive pads and traces at the mounting surface 202 of the module substrate 201.

According to an embodiment, and as indicated by arrows 297, 220, and 240, the driver amplifier die 210 and the carrier and peaking amplifier dies 230, 250 are oriented, with respect to each other, so that the driver amplification path 297 extends in a direction that is orthogonal to (i.e., perpendicular to) the direction in which the carrier and peaking amplification paths 220, 240 extend. As used herein, the term “signal path” refers to the path followed by an RF signal through a circuit. For example, a portion of a first signal path through the driver amplifier die 210 extends in a first direction (indicated by arrow 297) between the input and output terminals 211, 212 of die 210. Conversely, portions of second and third signal paths through the carrier amplifier die 230 and the peaking amplifier die 250 extend in a second direction (indicated by arrows 220, 240) between the RF input and output terminals 231, 232 (for the carrier amplifier die 230) and between the RF input and output terminals 251, 252 (for the peaking amplifier die 250). In the illustrated embodiment, the first and second directions are orthogonal to each other. The orthogonal orientation of the driver amplifier die 210 with respect to the carrier and peaking amplifier dies 230, 250 at least partially enables the driver, carrier, and peaking gate and drain bias voltage terminals 203, 218, 221, 206, 241, 207 to be located near the perimeter of the module 200. The placement of terminals 203, 218, 221, 206, 241, 207 near the perimeter of the module 200 enables a size reduction for the module 200, and a reduced BoM for the module 200, as described in more detail below.

As with the Doherty power amplifier 100 described in conjunction with FIG. 1, during operation of Doherty power amplifier module 200, an input RF signal is received from the separate system substrate (e.g., from trace 304, FIG. 3) through the RF input terminal 204, and conveyed to the driver amplifier die 210. According to one or more embodiments, a conductive path between the RF input terminal 204 and the driver amplifier die 210 may include various conductive traces, bondpads, and vias, and components of an input impedance matching circuit (generally indicated within box 208).

The driver amplifier die 210 includes a power transistor with a control terminal 211 (e.g., terminal 111, FIG. 1) (e.g., a gate terminal or driver amplifier input terminal), a first current-carrying terminal 212 (e.g., terminal 112, FIG. 1) (e.g., a drain terminal or driver amplifier output terminal), and a second current-carrying terminal (e.g., a source terminal, not numbered). The driver amplifier input terminal 211 may include, for example, a bondpad at a top surface of the driver amplifier die 210, which functions as an input to the driver amplifier die 210. As shown in FIG. 2, the driver amplifier input terminal 211 may be electrically coupled through one or more wirebonds to a conductive pad at the mounting surface 202 of the module substrate 201, and the conductive pad, in turn, may be electrically coupled to the RF input terminal 204 (through matching circuit 208).

The driver amplifier input terminal 211 is configured to receive the input RF signal, and the power transistor within the driver amplifier die 210 is configured to amplify the received input RF signal, and to produce an amplified RF signal at the driver amplifier output terminal 212. The driver amplifier output terminal 212 also may include, for example, a bondpad at a top surface of the driver amplifier die 210, which functions as an output of the driver amplifier die 210. Again, as shown in FIG. 2, the driver amplifier output terminal 212 may be electrically coupled through one or more wirebonds to another conductive pad at the mounting surface 202 of the module substrate 201, and the conductive pad, in turn, may be electrically coupled through one or more conductive traces and components to a power splitter 214 (e.g., power splitter 114, FIG. 1). The traces and components between the driver amplifier output terminal 212 and the power splitter 214 may provide an impedance matching circuit 228 (e.g., circuit 128, FIG. 1).

The carrier output circuit (e.g., circuit 164, FIG. 1) includes a first transmission path coupled between the carrier amplifier output terminal 232 and the combining node 262. More particularly, according to one or more embodiments, the carrier output circuit includes an output harmonic termination circuit 265 (e.g., circuit 165, FIG. 1), a shunt LC circuit (not numbered) (e.g., circuit 170, FIG. 1), and a first transmission line 275 (e.g., transmission line 175, FIG. 1), according to one or more embodiments.

A shunt LC circuit 209 (e.g., circuit 109, FIG. 1) is coupled between the driver amplifier control terminal 211 and a ground reference node. The ground reference node (and the other ground reference nodes identified below in the description of FIG. 2) may include a conductive pad at the mounting surface 202 of the module substrate 201, and a conductive via that extends from the conductive pad to the bottom surface of the module substrate 201. The conductive via may contact a portion of a patterned conductive layer on the bottom surface of the module substrate 201, which as explained earlier, may correspond to a ground reference node for the module 200 (as indicated with the downward-facing triangle coupled to the ground reference node pad/via).

According to one or more embodiments, the shunt LC circuit 209 includes an inductor (not numbered) and a capacitor (not numbered) coupled in series, with an intermediate node between the inductor and the capacitor. The intermediate node may correspond, for example, to a conductive pad at the mounting surface 202 of the module substrate 201.

According to one or more embodiments, the intermediate node is electrically coupled to and coincides with the driver gate bias voltage terminal 203. As discussed in conjunction with FIG. 1, the intermediate node and the driver gate bias voltage terminal 203 may correspond to an RF cold point in amplifier module 200, and the intermediate node and the driver gate bias voltage terminal 203 are purposefully located at or near the RF cold point, according to an embodiment. Accordingly, the driver gate bias voltage terminal 203 is a good point for provision of the gate bias voltage, V_{GD}, for the driver amplifier die 210.

Another shunt LC circuit 219 (e.g., circuit 119, FIG. 1) is coupled between the driver amplifier output terminal 212 and a ground reference node. According to one or more embodiments, the shunt LC circuit 219 includes an inductor (not numbered) and a capacitor (not numbered) coupled in series, with an intermediate node between the inductor and the capacitor. The intermediate node may correspond, for example, to a conductive pad at the mounting surface 202 of the module substrate 201.

According to one or more embodiments, the intermediate node is electrically coupled to and coincides with the driver drain bias voltage terminal 218. As discussed in conjunction with FIG. 1, the intermediate node and the driver drain bias voltage terminal 218 may correspond to an RF cold point in amplifier module 200, and the intermediate node and the driver drain bias voltage terminal 218 are purposefully located at or near the RF cold point, according to an embodiment. Accordingly, the driver drain bias voltage terminal 218 is a good point for provision of the drain bias voltage, V_{DD}, for the driver amplifier die 210.

It may be noted here that the orientation and placement of the driver amplifier die 210 on the module substrate 201 enables the driver gate and drain bias voltage terminals 203, 218 (and the corresponding RF cold points) to be placed near the perimeter of the module substrate 201. This, in turn, enables a driver gate and drain bias voltage circuits (e.g., circuits 113, 121, FIG. 1) to be placed on a system substrate next to the module 200, rather than requiring the driver gate and drain bias voltage circuits to be included within the module 200.

Referring briefly to FIG. 3, for example, a top view of a portion of an amplifier system 300 that includes the Doherty power amplifier module 200 of FIG. 2 is illustrated. More specifically, the amplifier system 300 includes a system substrate 396 with a plurality of conductive traces at a mounting surface (not numbered), including traces 303, 304, 305, 306, 307, 318, 321, and 341. The Doherty power amplifier module 200 is physically and electrically coupled (surface mounted) to the mounting surface of the system substrate 396 at least in part through conductive connections (e.g., solder or conductive adhesive) between the traces 303-307, 318, 321, 341 and the exposed portions of terminals 203-207, 218, 221, 241 at the bottom surface of the module 200. For example, terminal 204 is connected to an RF input trace 304, and terminal 205 is connected to an RF output trace 305.

Referring again to FIG. 2, the power splitter 214 has a power splitter input 215 (e.g., input 115, FIG. 1), a first power splitter output 216 (e.g., output 116, FIG. 1), and a second power splitter output 217 (e.g., output 117, FIG. 1). As described above, the power splitter input 215 is electrically coupled to the driver amplifier output terminal 212, and the power splitter 214 is configured to receive, at power splitter input 215, the amplified RF signal from the driver amplifier die 210. The power splitter 214 is further configured to divide the power of the input RF signal into a carrier input signal RF and a peaking input RF signal, which are produced at the first and second power splitter outputs 216, 217, respectively. In this manner, the power splitter 214 is configured to provide a carrier input RF signal to the carrier amplification path 220, and to provide a peaking input RF signal to the peaking amplification path 240. As discussed previously, the power splitter 214 divides the power of the amplified RF signal according to a carrier-to-peaking size ratio.

Power splitter 214 may be, for example, a Wilkinson-type splitter, a hybrid quadrature splitter, or another type of splitter. In some embodiments (e.g., when hybrid quadrature splitters are used), power splitter 214 is configured to produce a peaking input RF signal at the second power splitter output 217 that is about 90 degrees out of phase from (e.g., delayed from) the carrier input RF signal produced at the first power splitter output 216. In other embodiments (e.g., when Wilkinson-type splitters are used), power splitter 214 is configured to produce carrier and peaking input RF signals at the first and second power splitter outputs 216, 217 that are substantially in phase with each other.

The power splitter 214 may be implemented with a single surface mount component, or with a network of multiple discrete surface mount components that are electrically connected through conductive pads and traces of the module substrate 201. For simplicity, the power splitter 214 is generally indicated with a box.

The carrier amplification path 220 is electrically coupled to the first power splitter output 216. The carrier amplification path 220 includes a first phase adjustment circuit 222, a carrier IMN 224, a shunt LC circuit 223, and the carrier amplifier die 230. The first phase adjustment circuit 222 and the carrier IMN 224 are generally indicated with a box that corresponds to the carrier input circuit. As discussed previously, the first phase adjustment circuit 222 and the carrier IMN 224 are configured to ensure that the proper phase relationship is established between the carrier and peaking input RF signals when they arrive at the inputs 231, 251 to the carrier and peaking amplifier dies 230, 250, and also to incrementally increase the circuit impedance.

The shunt LC circuit 223 (e.g., circuit 123, FIG. 1) is coupled between the carrier amplifier input terminal 231 and a ground reference node. According to one or more embodiments, the shunt LC circuit 223 includes an inductor 225 (e.g., inductive element 125, FIG. 1) and a capacitor 226 (e.g., capacitor 126, FIG. 1) coupled in series, with an intermediate node (not numbered) between the inductor 225 and the capacitor 226. The intermediate node may correspond, for example, to a conductive pad at the mounting surface 202 of the module substrate 201.

According to one or more embodiments, the intermediate node is electrically coupled to and coincides with the carrier gate bias voltage terminal 221. As discussed in conjunction with FIG. 1, the intermediate node and the carrier gate bias voltage terminal 221 may correspond to an RF cold point in amplifier module 200, and the intermediate node and the carrier gate bias voltage terminal 221 are purposefully located at or near the RF cold point, according to an embodiment. Accordingly, the carrier gate bias voltage terminal 221 is a good point for provision of the gate bias voltage, V_{GC}, for the carrier amplifier die 230. It may be noted here that the orientation and placement of the carrier amplifier die 230 on the module substrate 201 enables the carrier gate bias voltage terminal 221 (and the RF cold point) to be placed near the perimeter of the module substrate 201. This, in turn, enables a carrier gate bias voltage circuit (e.g., circuit 127, FIG. 1) to be placed on a system substrate next to the module 200, rather than requiring the carrier gate bias voltage circuit to be included within the module 200.

Referring again briefly to FIG. 3, in accordance with an example embodiment, the carrier gate bias voltage terminal 221 (and the corresponding intermediate node/RF cold point) is connected to a carrier gate bias voltage trace 321 at the mounting surface of the system substrate 396. Although not shown in FIG. 3 (but indicated in FIG. 1), a gate bias voltage source may be coupled to a (non-illustrated) distal end of the carrier gate bias voltage trace 321, and the gate bias voltage source may be used to provide the carrier gate bias voltage, V_{GC}.

As shown in FIG. 3, a carrier gate bias voltage circuit 327 (e.g., circuit 127, FIG. 1) also is connected to the carrier gate bias voltage trace 321 near the carrier gate bias voltage terminal 221 (and thus near the RF cold point). In the present context, “near the RF cold point” means within an electrical length (at the fundamental frequency) of less than about 5 degrees. According to one or more embodiments, the carrier gate bias voltage circuit 327 may include a discrete capacitor and a discrete resistor connected to the mounting surface of the system substrate 396 and coupled in series between the carrier gate bias voltage trace 321 and a ground reference node of the system substrate 396.

Referring again to FIG. 2, the carrier amplifier die 230 includes a power transistor with a control terminal 231 (e.g., terminal 131, FIG. 1) (e.g., a gate terminal or carrier amplifier input terminal), a first current-carrying terminal 232 (e.g., terminal 132, FIG. 1) (e.g., a drain terminal or carrier amplifier output terminal), and a second current-carrying terminal (e.g., a source terminal, not numbered). The carrier amplifier input terminal 231 may include, for example, a bondpad at a top surface of the carrier amplifier die 230, which functions as an input to the carrier amplifier die 230. As shown in FIG. 2, the carrier amplifier input terminal 231 may be electrically coupled through one or more wirebonds to a conductive pad at the mounting surface 202 of the module substrate 201, and the conductive pad, in turn, may be electrically coupled to the first power splitter output 216 (through the first phase adjustment circuit 222 and the carrier IMN 224).

The carrier amplifier input terminal 231 is configured to receive the carrier input RF signal, and the power transistor within the carrier amplifier die 230 is configured to amplify the received carrier input RF signal, and to produce an amplified carrier RF signal at the carrier amplifier output terminal 232. The carrier amplifier output terminal 232 also may include, for example, a bondpad at a top surface of the carrier amplifier die 230, which functions as an output of the carrier amplifier die 230. Again, as shown in FIG. 2, the carrier amplifier output terminal 232 may be electrically coupled through one or more wirebonds to another conductive pad at the mounting surface 202 of the module substrate 201, and the conductive pad, in turn, may be electrically coupled through one or more conductive traces and components to the combining node 262 (e.g., combining node 162, FIG. 1).

The peaking amplification path 240 is electrically coupled to the second power splitter output 217. The peaking amplification path 240 includes a second phase adjustment circuit 242, a peaking IMN 244, a shunt LC circuit 243, and the peaking amplifier die 250. The second phase adjustment circuit 242 and the peaking IMN 244 are generally indicated with a box that corresponds to the peaking input circuit. As discussed previously, the second phase adjustment circuit 242 and the peaking IMN 244 are configured to ensure that the proper phase relationship is established between the carrier and peaking input RF signals when they arrive at the inputs 231, 251 to the carrier and peaking amplifier dies 230, 250, and also to incrementally increase the circuit impedance.

The shunt LC circuit 243 (e.g., circuit 143, FIG. 1) is coupled between the peaking amplifier input terminal 251 and a ground reference node. According to one or more embodiments, the shunt LC circuit 243 includes an inductor 245 (e.g., inductive element 145, FIG. 1) and a capacitor 246 (e.g., capacitor 146, FIG. 1) coupled in series, with an intermediate node (not numbered) between the inductor 245 and the capacitor 246. The intermediate node may correspond, for example, to a conductive pad at the mounting surface 202 of the module substrate 201.

According to one or more embodiments, the intermediate node is electrically coupled to and coincides with the peaking gate bias voltage terminal 241. As discussed in conjunction with FIG. 1, the intermediate node and the peaking gate bias voltage terminal 241 may correspond to an RF cold point in amplifier module 200, and the intermediate node and the peaking gate bias voltage terminal 241 are purposefully located at or near the RF cold point, according to an embodiment. Accordingly, the peaking gate bias voltage terminal 241 is a good point for provision of the gate bias voltage, V_{GP}, for the peaking amplifier die 250. It may be noted here that the orientation and placement of the peaking amplifier die 250 on the module substrate 201 enables the peaking gate bias voltage terminal 241 (and the RF cold point) to be placed near the perimeter of the module substrate 201. This, in turn, enables a peaking gate bias voltage circuit (e.g., circuit 147, FIG. 1) to be placed on a system substrate next to the module 200, rather than requiring the peaking gate bias voltage circuit to be included within the module 200.

Referring again briefly to FIG. 3, in accordance with an example embodiment, the peaking gate bias voltage terminal 241 (and the corresponding intermediate node/RF cold point) is connected to a peaking gate bias voltage trace 341 at the mounting surface of the system substrate 396. Although not shown in FIG. 3 (but indicated in FIG. 1), a gate bias voltage source may be coupled to a (non-illustrated) distal end of the peaking gate bias voltage trace 341, and the gate bias voltage source may be used to provide the peaking gate bias voltage, V_{GP}.

As shown in FIG. 3, a peaking gate bias voltage circuit 347 (e.g., circuit 147, FIG. 1) also is connected to the peaking gate bias voltage trace 341 near the peaking gate bias voltage terminal 241 (and thus near the RF cold point). According to one or more embodiments, the peaking gate bias voltage circuit 347 may include a discrete capacitor and a discrete resistor connected to the mounting surface of the system substrate 396 and coupled in series between the peaking gate bias voltage trace 341 and a ground reference node of the system substrate 396.

Referring again to FIG. 2, the peaking amplifier die 250 includes a power transistor with a control terminal 251 (e.g., terminal 151, FIG. 1) (e.g., a gate terminal or peaking amplifier input terminal), a first current-carrying terminal 252 (e.g., terminal 152, FIG. 1) (e.g., a drain terminal or peaking amplifier output terminal), and a second current-carrying terminal (e.g., a source terminal, not numbered). The peaking amplifier input terminal 251 may include, for example, a bondpad at a top surface of the peaking amplifier die 250, which functions as an input to the peaking amplifier die 250. As shown in FIG. 2, the peaking amplifier input terminal 251 may be electrically coupled through one or more wirebonds to a conductive pad at the mounting surface 202 of the module substrate 201, and the conductive pad, in turn, may be electrically coupled to the second power splitter output 217 (through the second phase adjustment circuit 242 and the peaking IMN 244).

The peaking amplifier input terminal 251 is configured to receive the peaking input RF signal, and the power transistor within the peaking amplifier die 250 is configured to amplify the received peaking input RF signal, and to produce an amplified peaking RF signal at the peaking amplifier output terminal 252. The peaking amplifier output terminal 252 also may include, for example, a bondpad at a top surface of the peaking amplifier die 250, which functions as an output of the peaking amplifier die 250. Again, as shown in FIG. 2, the peaking amplifier output terminal 252 may be electrically coupled through one or more wirebonds to another conductive pad at the mounting surface 202 of the module substrate 201, and the conductive pad, in turn, may be electrically coupled through one or more conductive traces and components to the combining node 262 (e.g., combining node 162, FIG. 1).

The output combining circuit 260 (e.g., circuit 160, FIG. 1) is electrically coupled to the carrier and peaking amplifier output terminals 232, 252. According to one or more embodiments, the output combining circuit 260 includes the combining node 262, a carrier output circuit (not numbered) (e.g., circuit 164, FIG. 1), and a peaking output circuit (not numbered) (e.g., circuit 180, FIG. 1).

The carrier output circuit (e.g., circuit 164, FIG. 1) includes a first transmission path coupled between the carrier amplifier output terminal 232 and the combining node 262. More particularly, according to one or more embodiments, the carrier output circuit includes an output harmonic termination circuit 265 (e.g., circuit 165, FIG. 1), a shunt LC circuit 270 (e.g., circuit 170, FIG. 1), and a first transmission line 275 (e.g., transmission line 175, FIG. 1), according to one or more embodiments.

The output harmonic termination circuit 265 is coupled between the carrier amplifier output terminal 232 (or more particularly, the intermediate node 269) and a ground reference node. As discussed previously, the output harmonic termination circuit 265 is configured to resonate at or near a second harmonic frequency of the fundamental frequency. According to one or more embodiments, the harmonic termination circuit 265 includes a series inductive element 266 (e.g., inductive element 166, FIG. 1), an inductor 267 (e.g., inductive element 167, FIG. 1), and a capacitor 268 (e.g., capacitor 168, FIG. 1).

The series inductive element 266 may include, for example, a plurality of wirebonds with first ends (collectively, a “first terminal”) coupled to the carrier amplifier output terminal 232 and second ends (collectively, a “second terminal”) coupled to an intermediate node 269 (e.g., node 169, FIG. 1). The intermediate node 269 may correspond, for example, to a first end of the transmission line 275. As discussed previously, the series inductive element 266 also forms a portion of the first transmission path, and contributes to output impedance matching between the carrier amplifier output terminal 232 and the combining node 262. In addition, the series inductive element 266 functions to establish a correct harmonic termination location (together with inductor 267 and capacitor 268) to ensure high efficiency.

The inductor 267 and the capacitor 268 are coupled in series between the intermediate node 269 and the ground reference node. The inductor 267 and the capacitor 268 may, for example, be discrete surface mount components, each with first and second terminals that are coupled to conductive traces and pads at the mounting surface 202 of the module substrate 201.

The shunt LC circuit 270 also is coupled between the carrier amplifier output terminal 232 (or more particularly, the intermediate node 269) and a ground reference node. As discussed previously, the shunt LC circuit 270 is configured to adjust the effective output capacitance (e.g., capacitance 134, FIG. 1) of the carrier amplifier die 230. According to one or more embodiments, the shunt LC circuit 270 includes an inductor 271 (e.g., inductive element 171, FIG. 1) and a capacitor 273 (e.g., capacitor 173, FIG. 1) coupled in series, with an intermediate node 272 (e.g., node 172, FIG. 1) between the inductor 271 and the capacitor 273. The intermediate node 272 may correspond, for example, to a conductive pad at the mounting surface 202 of the module substrate 201.

According to one or more embodiments, the intermediate node 272 is electrically coupled to and coincides with the carrier drain bias voltage terminal 206. As discussed in conjunction with FIG. 1, the intermediate node 272 and the carrier drain bias voltage terminal 206 may correspond to an RF cold point in amplifier module 200, and the intermediate node 272 and the carrier drain bias voltage terminal 206 are purposefully located at or near the RF cold point, according to an embodiment. Accordingly, the carrier drain bias voltage terminal 206 is a good point for provision of the drain bias voltage, V_{DC}, for the carrier amplifier die 230. It may be noted here that the orientation and placement of the carrier amplifier die 230 on the module substrate 201 enables the series inductive element 266 (e.g., wirebonds), the intermediate node 269, and the inductor 271 to be oriented and located to enable the carrier drain bias voltage terminal 206 (and the RF cold point) to be placed near the perimeter of the module substrate 201. This, in turn, enables a carrier drain bias voltage circuit (e.g., circuit 174, FIG. 1) to be placed on a system substrate next to the module 200, rather than requiring the carrier drain bias voltage circuit to be included within the module 200.

Referring again briefly to FIG. 3, in accordance with an example embodiment, the carrier drain bias voltage terminal 206 (and the corresponding intermediate node/RF cold point 272) is connected to a carrier drain bias voltage trace 306 at the mounting surface of the system substrate 396. Although not shown in FIG. 3 (but indicated in FIG. 1), a drain bias voltage source may be coupled to a (non-illustrated) distal end of the carrier drain bias voltage trace 306, and the drain bias voltage source may be used to provide the carrier drain bias voltage, V_{DC}. As mentioned previously, to ensure proper Doherty amplifier operation, the carrier amplifier die 230 is biased to operate in class AB mode or deep class AB mode.

As shown in FIG. 3, a carrier drain bias voltage circuit 374 (e.g., circuit 174, FIG. 1) also is connected to the carrier drain bias voltage trace 306 near the carrier drain bias voltage terminal 206 (and thus near the RF cold point). According to one or more embodiments, the carrier drain bias voltage circuit 374 may include a discrete capacitor and a discrete resistor connected to the mounting surface of the system substrate 396 and coupled in series between the carrier drain bias voltage trace 306 and a ground reference node of the system substrate 396.

Again, a significant technical advantage is achieved by designing the module 200 so that the carrier gate and drain bias voltage terminals 221, 206 (and the corresponding RF cold points) are located near the perimeter of the module 200. More specifically, the placement of terminals 221, 206 near the perimeter of the module 200 enables the carrier gate and drain bias voltage circuits 327, 374 to be placed on the system substrate 396, and the module 200 does not need to be sized to accommodate the carrier gate and drain bias voltage circuits 327, 374. This enables a size reduction for the module 200, and a reduced BoM for the module 200.

Referring again to FIG. 2, the first transmission line 275 has a first end coupled to the intermediate node 269 and a second end coupled to the combining node 262. According to one or more embodiments, the first transmission line 275 is configured to impart a phase delay to the amplified carrier output RF signal produced by the carrier amplifier die 230, and also to impart an impedance inversion. A shunt capacitor 276 may be coupled along the first transmission line 275, in some embodiments. The shunt capacitor 276 may add some tuning flexibility to the carrier output circuit.

As mentioned in conjunction with FIG. 1, the carrier output circuit is characterized by a first electrical length at the fundamental frequency between the carrier amplifier output terminal 232 and the combining node 262. According to one or more embodiments, the first electrical length (as affected by drain-source capacitance 134, FIG. 1) includes the electrical length of the series inductive element 266 and the electrical length of the first transmission line 275. The total first electrical length is in a range of about 60 degrees to about 90 degrees at the fundamental frequency.

The peaking output circuit (e.g., circuit 180, FIG. 1) of the output combining circuit 260 includes a second transmission path coupled between the peaking amplifier output terminal 252 and the combining node 262. More particularly, according to one or more embodiments, the peaking output circuit includes a series inductive element 281 (e.g., element 181, FIG. 1), a shunt LC circuit 282 (e.g., circuit 182, FIG. 1), a second (hybrid) transmission line 287 (e.g., transmission line 187, FIG. 1), a third transmission line 289 (e.g., transmission line 189, FIG. 1), and a shunt capacitor 292 (e.g., capacitor 192, FIG. 1), according to one or more embodiments.

The series inductive element 281 may include, for example, a plurality of wirebonds with first ends (collectively, a “first terminal”) coupled to the peaking amplifier output terminal 252 and second ends (collectively, a “second terminal”) coupled to an intermediate node 277 (e.g., node 177, FIG. 1). The intermediate node 277 may correspond, for example, to a first end of the second transmission line 287.

The shunt LC circuit 282 also is coupled between the peaking amplifier output terminal 252 (or more particularly, the intermediate node 277) and a ground reference node. As discussed previously, the shunt LC circuit 282 is configured to adjust the effective output capacitance (e.g., capacitance 154, FIG. 1) of the peaking amplifier die 250. According to one or more embodiments, the shunt LC circuit 282 includes an inductor 283 (e.g., inductive element 183, FIG. 1) and a capacitor 285 (e.g., capacitor 185, FIG. 1) coupled in series, with an intermediate node 284 (e.g., node 184, FIG. 1) between the inductor 283 and the capacitor 285. The intermediate node 284 may correspond, for example, to a conductive pad at the mounting surface 202 of the module substrate 201.

According to one or more embodiments, the intermediate node 284 is electrically coupled to and coincides with the peaking drain bias voltage terminal 207. As discussed in conjunction with FIG. 1, the intermediate node 284 and the peaking drain bias voltage terminal 207 may correspond to another RF cold point in amplifier module 200, and the intermediate node 284 and the peaking drain bias voltage terminal 207 are purposefully located at or near the RF cold point, according to an embodiment. Accordingly, the peaking drain bias voltage terminal 207 is a good point for provision of the drain bias voltage, V_{DP}, for the peaking amplifier die 250.

Again, it may be noted here that the orientation and placement of the peaking amplifier die 250 on the module substrate 201 enables the series inductive element 281 (e.g., wirebonds), the intermediate node (not numbered), and the inductor 283 to be oriented and located to enable the peaking drain bias voltage terminal 207 (and the RF cold point) to be placed near the perimeter of the module substrate 201. This, in turn, enables a peaking drain bias voltage circuit (e.g., circuit 186, FIG. 1) to be placed on a system substrate next to the module 200, rather than requiring the carrier drain bias voltage circuit to be included within the module 200.

Referring again briefly to FIG. 3, for example, the peaking drain bias voltage terminal 207 (and the corresponding intermediate node/RF cold point 284) is connected to a peaking drain bias voltage trace 307 at the mounting surface of the system substrate 396. Although not shown in FIG. 3 (but indicated in FIG. 1), a drain bias voltage source may be coupled to a (non-illustrated) distal end of the peaking drain bias voltage trace 307, and the drain bias voltage source may be used to provide the peaking drain bias voltage, V_{DP}. As mentioned previously, to ensure proper Doherty amplifier operation, the peaking amplifier die 250 is biased to operate in class C mode or deep class C mode. In some configurations, the peaking amplifier die 250 may be biased to operate in class B or class J mode.

As shown in FIG. 3, a peaking drain bias voltage circuit 386 (e.g., circuit 186, FIG. 1) also is connected to the peaking drain bias voltage trace 307 near the peaking drain bias voltage terminal 207 (and thus near the RF cold point). According to one or more embodiments, the peaking drain bias voltage circuit 386 may include a discrete capacitor and a discrete resistor connected to the mounting surface of the system substrate 396 and coupled in series between the peaking drain bias voltage trace 307 and a ground reference node of the system substrate 396.

Once again, a significant technical advantage is achieved by designing the module 200 so that the peaking gate and drain bias voltage terminals 241, 207 (and the corresponding RF cold points) are located near the perimeter of the module 200. More specifically, the placement of terminals 241, 207 near the perimeter of the module 200 enables the peaking gate and drain bias voltage circuits 347, 386 to be placed on the system substrate 396, and the module 200 does not need to be sized to accommodate the peaking gate and drain bias voltage circuits 347, 386. This enables a size reduction for the module 200, and a reduced BoM for the module 200.

Referring again to FIG. 2, the second and third transmission lines 287, 289 are coupled in series between the peaking amplifier output terminal 252 and the combining node 262, with the shunt capacitor 292 being connected to an intermediate node 288 (e.g., node 188, FIG. 1) between the second and third transmission lines 287, 289. More specifically, the second transmission line 287 has a first end coupled to the intermediate node 277 and a second end coupled to the intermediate node 288. According to one or more embodiments, and as illustrated in FIG. 2, the second transmission line 287 may be a “hybrid” transmission line, which includes a series-coupled sequence of a first transmission line segment coupled to the intermediate node 277, a second transmission line segment coupled to the intermediate node 288, and a set of wirebonds coupled between the first and second transmission line segments. The configuration of the wirebonds (e.g., number of wirebonds, wirebond height, and wirebond length) may be adjusted to allow for tunability of the second (hybrid) transmission line 287. According to one or more other embodiments, the second transmission line 287 may be implemented as a single continuous conductive trace on the module substrate 201 (without wirebonds). However it is implemented, the second transmission line 287 is configured to impart a phase delay to the amplified peaking output RF signal produced by the peaking amplifier die 250.

The shunt capacitor 292 has a first terminal coupled to the intermediate node 288 and a second terminal coupled to a ground reference node. As discussed in conjunction with FIG. 1, the combination of the second and third transmission lines 287, 289 and the shunt capacitor 292 enables the physical size of the peaking output circuit to be reduced, in comparison with a conventional peaking output circuit.

The third transmission line 289 has a first end coupled to the intermediate node 288 and a second end coupled to the combining node 262. The third transmission line 289 is configured to impart an additional phase delay to the amplified peaking output RF signal produced by the peaking amplifier die 250. A shunt capacitor 290 may be coupled along the third transmission line 289, in some embodiments. The shunt capacitor 290 may add additional tuning flexibility to the peaking output circuit.

As mentioned in connection with FIG. 1, the peaking output circuit is characterized by a second electrical length at the fundamental frequency between the peaking amplifier output terminal 252 and the combining node 262. According to one or more embodiments, the second electrical length (including the combined electrical lengths of the second and third transmission lines 287, 289 and as affected by drain-source capacitance 154, FIG. 1, and shunt capacitor 292) is in a range of about 140 degrees to about 180 degrees at the fundamental frequency.

As also discussed in conjunction with FIG. 1, the second transmission path between the peaking amplifier output terminal 252 and the combining node 262 is configured in a manner that is more compact in comparison with a conventional Doherty amplifier output circuit. More specifically, by including the shunt capacitor 292 between the second and third transmission lines 287, 289, the total physical and electrical length of the second and third transmission lines 287, 289 may be shorter than would be required with a single transmission line (with no shunt capacitance). Thus, utilizing the shunt capacitor 292 has the technical advantage of enabling the peaking output circuit to be more compact than a conventional peaking output circuit.

The combining node 262 is coupled to the carrier and peaking output circuits. The combining node 262 is configured to receive the amplified carrier output signal from the carrier output circuit, to receive the amplified peaking signal from the peaking output circuit, and to combine the amplified carrier output signal with the amplified peaking output signal.

The output impedance transformer 294 (e.g., transformer 194, FIG. 1) is electrically coupled between the combining node 262 and the RF output terminal 205. As shown in FIG. 2, the output impedance transformer 294 may include a fourth transmission line and a plurality of shunt capacitors (not numbered). A DC blocking capacitor 295 (e.g., capacitor 195, FIG. 1) also may be coupled along the output impedance transformer 294 between the combining node 262 and the RF output terminal 205.

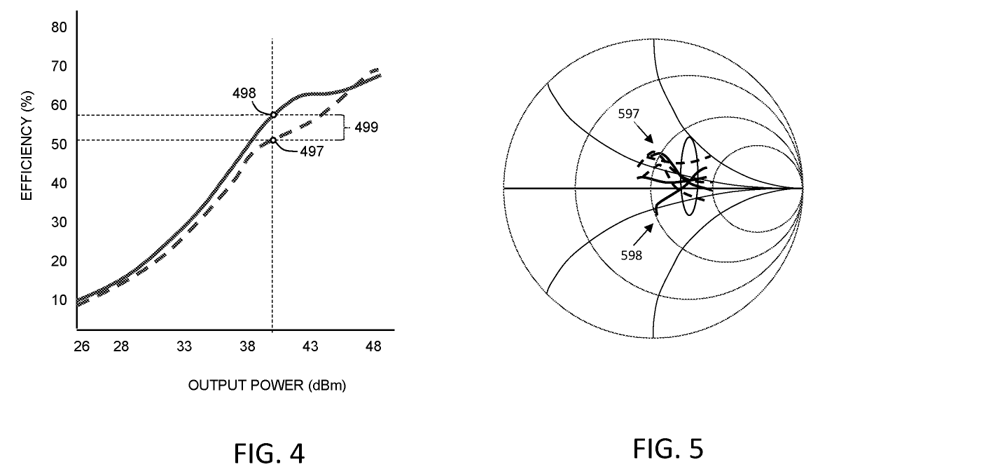

FIG. 4 is a graph illustrating power efficiency curves 497, 498 for a conventional 90/0 Doherty power amplifier (dashed line) with an output harmonic termination circuit at the combining node, and for an embodiment of a 90/180 Doherty power amplifier (solid line) with an output harmonic termination circuit at the carrier amplifier output (e.g., Doherty power amplifier 100, 200, FIGS. 1, 2), respectively. The power efficiency curves 497, 498 were generated using simulations of both power amplifiers with large signal, one-tone, carrier wave input signals.

The power efficiency curves 497, 498 illustrate that implementation of a 90/180 output combining circuit (e.g., circuit 160, 260, FIGS. 1, 2) according to the above-described embodiments with an output harmonic termination circuit (e.g., circuit 165, 265, FIGS. 1, 2) coupled to the output of the carrier amplifier may result in an efficiency increase 499 of several points, particularly in the output power region above 40 dBm. Overall, embodiments of 90/180 Doherty power amplifiers described herein are characterized by higher efficiency than a conventional 90/0 Doherty power amplifier due to the wider bandwidth associated with the 90/180 topology. The inclusion of an output harmonic termination circuit (e.g., circuits 165, 265, FIGS. 1, 2) may even further improve efficiency.

FIG. 5 is a Smith chart illustrating efficiency spread for a conventional 90/0 Doherty power amplifier (dashed lines 597) with an output harmonic termination circuit at the combining node, and for an embodiment of a 90/180 Doherty power amplifier (solid lines 598) with an output harmonic termination circuit at the carrier amplifier output (e.g., Doherty power amplifier 100, 200, FIGS. 1, 2), respectively. Comparison of the efficiency curves 597, 598 show that embodiments of Doherty power amplifiers described herein may exhibit less spread at (Zmod), which may particularly be a result of using the 90/180 Doherty topology, as opposed to the 90/0 Doherty topology. The tighter efficiency curves 598 for embodiments of 90/180 Doherty power amplifiers discussed herein correlates to a narrower efficiency spread across frequency. Particularly, the efficiency of the embodiments of Doherty power amplifiers discussed herein is higher across frequency, in comparison with a conventional 90/0 Doherty power amplifier.

An embodiment of an amplifier module includes a module substrate with a mounting surface, a plurality of terminals coupled to the module substrate, a carrier amplifier die connected to the mounting surface, a peaking amplifier die connected to the mounting surface, and an output combining circuit coupled to the module substrate. The plurality of terminals includes an output terminal. The carrier amplifier die includes a carrier amplifier output terminal, and the carrier amplifier die is configured to produce an amplified carrier output signal at the carrier amplifier output terminal. The peaking amplifier die includes a peaking amplifier output terminal, and the peaking amplifier die is configured to produce an amplified peaking output signal at the peaking amplifier output terminal. The output combining circuit includes a combining node configured to combine the amplified carrier output signal with the amplified peaking output signal, a carrier output circuit coupled between the carrier amplifier output terminal and the combining node, and a peaking output circuit coupled between the peaking amplifier output terminal and the combining node. The carrier output circuit is characterized by a first electrical length at a fundamental frequency of operation of the Doherty power amplifier, and the carrier output circuit includes a first transmission line coupled between the carrier amplifier output terminal and the combining node, and a harmonic termination circuit coupled between the carrier amplifier output terminal and a ground reference node. The harmonic termination circuit is configured to resonate at or near a second harmonic frequency of the fundamental frequency. The peaking output circuit is characterized by a second electrical length at the fundamental frequency of operation, and the peaking output circuit includes a second transmission line and a third transmission line coupled in series between the peaking amplifier output terminal and the combining node, with a first intermediate node between the second and third transmission lines, and a first capacitor with a first terminal coupled to the first intermediate node and a second terminal coupled to a ground reference node.

An embodiment of a Doherty power amplifier includes a system substrate, a carrier drain bias voltage circuit connected to the system substrate, a peaking drain bias voltage circuit connected to the system substrate, and an amplifier module connected to the system substrate. The amplifier module includes a module substrate with a mounting surface, a plurality of terminals connected to the module substrate, a carrier amplifier die connected to the mounting surface, a peaking amplifier die connected to the mounting surface, and an output combining circuit coupled to the module substrate. The plurality of terminals includes an output terminal, a carrier drain bias voltage terminal coupled through the system substrate to the carrier drain bias voltage circuit, and a peaking drain bias voltage terminal coupled through the system substrate to the peaking drain bias voltage circuit. The carrier amplifier die includes a carrier amplifier output terminal, and the carrier amplifier die is configured to produce an amplified carrier output signal at the carrier amplifier output terminal. The peaking amplifier die includes a peaking amplifier output terminal, and the peaking amplifier die is configured to produce an amplified peaking output signal at the peaking amplifier output terminal. The output combining circuit includes a combining node, a carrier output circuit, and a peaking output circuit. The combining node is configured to combine the amplified carrier output signal with the amplified peaking output signal. The carrier output circuit is coupled between the carrier amplifier output terminal and the combining node, and the carrier output circuit is characterized by a first electrical length at a fundamental frequency of operation of the Doherty power amplifier. The carrier output circuit includes a first transmission line coupled between the carrier amplifier output terminal and the combining node, and a harmonic termination circuit coupled between the carrier amplifier output terminal and a ground reference node. The harmonic termination circuit is configured to resonate at or near a second harmonic frequency of the fundamental frequency. The peaking output circuit is coupled between the peaking amplifier output terminal and the combining node, and the peaking output circuit is characterized by a second electrical length at the fundamental frequency of operation. The peaking output circuit includes a second transmission line and a third transmission line coupled in series between the peaking amplifier output terminal and the combining node, with a first intermediate node between the second and third transmission lines, and a first capacitor with a first terminal coupled to the first intermediate node and a second terminal coupled to a ground reference node.

An embodiment of a Doherty power amplifier includes a carrier amplifier, a peaking amplifier, and an output combining circuit. The carrier amplifier has a carrier amplifier output terminal, and the carrier amplifier is configured to produce an amplified carrier output signal at the carrier amplifier output terminal. The peaking amplifier has a peaking amplifier output terminal, and the peaking amplifier is configured to produce an amplified peaking output signal at the peaking amplifier output terminal. The output combining circuit includes a combining node, a carrier output circuit, and a peaking output circuit. The combining node is configured to combine the amplified carrier output signal with the amplified peaking output signal. The carrier output circuit is coupled between the carrier amplifier output terminal and the combining node, and the carrier output circuit is characterized by a first electrical length at a fundamental frequency of operation of the Doherty power amplifier. The carrier output circuit includes a first transmission line coupled between the carrier amplifier output terminal and the combining node, and a harmonic termination circuit coupled between the carrier amplifier output terminal and a ground reference node. The harmonic termination circuit is configured to resonate at or near a second harmonic frequency of the fundamental frequency. The peaking output circuit is coupled between the peaking amplifier output terminal and the combining node, and the peaking output circuit is characterized by a second electrical length at the fundamental frequency of operation. The peaking output circuit includes a second transmission line and a third transmission line coupled in series between the peaking amplifier output terminal and the combining node, with a first intermediate node between the second and third transmission lines, and a first capacitor with a first terminal coupled to the first intermediate node and a second terminal coupled to a ground reference node.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first,” “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

As used herein, the words “exemplary” and “example” mean “serving as an example, instance, or illustration.” Any implementation described herein as exemplary or an example is not necessarily to be construed as preferred or advantageous over other implementations. Furthermore, there is no intention to be bound by any expressed or implied theory presented in the preceding technical field, background, or detailed description.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. An amplifier module comprising:
a module substrate with a mounting surface;
a plurality of terminals coupled to the module substrate, wherein the plurality of terminals includes an output terminal;
a carrier amplifier die connected to the mounting surface and including a carrier amplifier output terminal, wherein the carrier amplifier die is configured to produce an amplified carrier output signal at the carrier amplifier output terminal;
a peaking amplifier die connected to the mounting surface and including a peaking amplifier output terminal, wherein the peaking amplifier die is configured to produce an amplified peaking output signal at the peaking amplifier output terminal;
an output combining circuit coupled to the module substrate that includes
a combining node configured to combine the amplified carrier output signal with the amplified peaking output signal,
a carrier output circuit coupled between the carrier amplifier output terminal and the combining node, wherein the carrier output circuit is characterized by a first electrical length at a fundamental frequency of operation of the Doherty power amplifier, and the carrier output circuit includes
a first transmission line coupled between the carrier amplifier output terminal and the combining node, and
a harmonic termination circuit coupled between the carrier amplifier output terminal and a ground reference node, wherein the harmonic termination circuit is configured to resonate at or near a second harmonic frequency of the fundamental frequency; and
a peaking output circuit coupled between the peaking amplifier output terminal and the combining node, wherein the peaking output circuit is characterized by a second electrical length at the fundamental frequency of operation, and the peaking output circuit includes
a second transmission line and a third transmission line coupled in series between the peaking amplifier output terminal and the combining node, with a first intermediate node between the second and third transmission lines, and
a first capacitor with a first terminal coupled to the first intermediate node and a second terminal coupled to the ground reference node.

2. The amplifier module of claim 1, wherein the carrier output circuit further comprises:
a first inductive element coupled between the carrier amplifier output terminal and a second intermediate node.

3. The amplifier module of claim 2, wherein the harmonic termination circuit comprises:
a second inductive element and a second capacitor coupled in series between the second intermediate node and the ground reference node.

4. The amplifier module of claim 3, wherein the first inductive element comprises a plurality of wirebonds with first ends connected to the carrier amplifier output terminal and second ends coupled to the second intermediate node.

5. The amplifier module of claim 2, wherein:
the plurality of terminals further includes a carrier drain bias voltage terminal and a peaking drain bias voltage terminal; and
the amplifier module further includes
a first shunt inductor-capacitor circuit that includes a third inductive element and a third capacitor coupled in series between the second intermediate node and the ground reference node, wherein a third intermediate node between the third inductive element and the third capacitor corresponds to a first radio frequency (RF) cold point, and the third intermediate node is connected to the carrier drain bias voltage terminal; and
a second shunt inductor-capacitor circuit that includes a fourth inductive element and a fourth capacitor coupled in series between the peaking amplifier output terminal and the ground reference node, wherein a fourth intermediate node between the fourth inductive element and the fourth capacitor corresponds to a second RF cold point, and the fourth intermediate node is connected to the peaking drain bias voltage terminal.

6. The amplifier module of claim 1, wherein the second transmission line is a hybrid transmission line that comprises:
a series-coupled sequence of a first transmission line segment coupled to the first intermediate node, a second transmission line segment coupled to the first intermediate node, and a set of wirebonds coupled between the first and second transmission line segments.

7. The amplifier module of claim 1, further comprising:
a second capacitor with a first terminal connected to the first transmission line and a second terminal coupled to the ground reference node; and
a third capacitor with a first terminal connected to the third transmission line and a second terminal coupled to the ground reference node.

8. The amplifier module of claim 1, wherein:
the carrier amplifier die includes a first power transistor with a first gate terminal, a first drain terminal, and a first source terminal, wherein the first gate terminal corresponds to a carrier amplifier input terminal, and the first drain terminal corresponds to the carrier amplifier output terminal;
the carrier amplifier die is characterized by a first drain-source capacitance between the first drain terminal and the first source terminal;
the carrier output circuit, including an effect the first drain-source capacitance, is characterized by a first electrical length in a range of 60 degrees to 90 degrees at the fundamental frequency;
the peaking amplifier die includes a second power transistor with a second gate terminal, a second drain terminal, and a second source terminal, wherein the second gate terminal corresponds to a peaking amplifier input terminal, and the second drain terminal corresponds to the peaking amplifier output terminal;
the peaking amplifier is characterized by a second drain-source capacitance between the second drain terminal and the second source terminal; and
the peaking output circuit, including an effect of the second drain-source capacitance, is characterized by a second electrical length in a range of 140 degrees to 180 degrees at the fundamental frequency.

9. The amplifier module of claim 8, wherein the plurality of terminals further includes a radio frequency (RF) input, and the amplifier module further comprises:
a power splitter connected to the module substrate with a power splitter input, a first power splitter output, and a second power splitter output, wherein the power splitter input is coupled to the RF input and is configured to receive an input RF signal, the power splitter is configured to split a power of the input RF signal into a carrier input signal that is provided at the first power splitter output and a peaking input signal that is provided at the second power splitter output;
a carrier input circuit connected to the module substrate and coupled between the first power splitter output and the carrier amplifier input terminal, wherein the carrier input circuit is characterized by a third electrical length at the fundamental frequency; and
a peaking input circuit connected to the module substrate and coupled between the second power splitter output and the peaking amplifier input terminal, wherein the peaking input circuit is characterized by a fourth electrical length at the fundamental frequency, and
wherein the first electrical length plus the third electrical length is equal to the second electrical length plus the fourth electrical length at the fundamental frequency.

10. The amplifier module of claim 9, further comprising:
a driver amplifier die connected to the mounting surface and including a driver amplifier input terminal and a driver amplifier output terminal, wherein the driver amplifier input terminal is coupled to the RF input, and the driver amplifier output terminal is coupled to the power splitter input.

11. The amplifier module of claim 10, wherein:
the driver amplifier die, the carrier amplifier die, and the peaking amplifier die are oriented, with respect to each other, so that a driver amplification path through the driver amplifier die extends in a first direction, a carrier amplification path through the carrier amplifier die extends in a second direction, and a peaking amplification path through the peaking amplifier die extends in the second direction, wherein the first direction and the second direction are orthogonal to each other.

12. A Doherty power amplifier comprising:
a system substrate;
a carrier drain bias voltage circuit connected to the system substrate;
a peaking drain bias voltage circuit connected to the system substrate;
an amplifier module connected to the system substrate and including
a module substrate with a mounting surface,
a plurality of terminals connected to the module substrate, wherein the plurality of terminals includes an output terminal, a carrier drain bias voltage terminal coupled through the system substrate to the carrier drain bias voltage circuit, and a peaking drain bias voltage terminal coupled through the system substrate to the peaking drain bias voltage circuit,
a carrier amplifier die connected to the mounting surface and including a carrier amplifier output terminal, wherein the carrier amplifier die is configured to produce an amplified carrier output signal at the carrier amplifier output terminal,
a peaking amplifier die connected to the mounting surface and including a peaking amplifier output terminal, wherein the peaking amplifier die is configured to produce an amplified peaking output signal at the peaking amplifier output terminal,
an output combining circuit coupled to the module substrate that includes
a combining node configured to combine the amplified carrier output signal with the amplified peaking output signal,
a carrier output circuit coupled between the carrier amplifier output terminal and the combining node, wherein the carrier output circuit is characterized by a first electrical length at a fundamental frequency of operation of the Doherty power amplifier, and the carrier output circuit includes
a first transmission line coupled between the carrier amplifier output terminal and the combining node, and
a harmonic termination circuit coupled between the carrier amplifier output terminal and a ground reference node, wherein the harmonic termination circuit is configured to resonate at or near a second harmonic frequency of the fundamental frequency, and
a peaking output circuit coupled between the peaking amplifier output terminal and the combining node, wherein the peaking output circuit is characterized by a second electrical length at the fundamental frequency of operation, and the peaking output circuit includes
a second transmission line and a third transmission line coupled in series between the peaking amplifier output terminal and the combining node, with a first intermediate node between the second and third transmission lines, and
a first capacitor with a first terminal coupled to the first intermediate node and a second terminal coupled to the ground reference node.

13. The Doherty power amplifier of claim 12, wherein the harmonic termination circuit comprises:
a second inductive element and a second capacitor coupled in series between the carrier amplifier output terminal and the ground reference node.

14. The Doherty power amplifier of claim 13, further comprising:
a first shunt inductor-capacitor circuit that includes a third inductive element and a third capacitor coupled in series between the carrier amplifier output terminal and the ground reference node, wherein a second intermediate node between the third inductive element and the third capacitor corresponds to a first radio frequency (RF) cold point, and the second intermediate node is connected to the carrier drain bias voltage terminal; and
a second shunt inductor-capacitor circuit that includes a fourth inductive element and a fourth capacitor coupled in series between the peaking amplifier output terminal and the ground reference node, wherein a third intermediate node between the fourth inductive element and the fourth capacitor corresponds to a second RF cold point, and the third intermediate node is connected to the peaking drain bias voltage terminal.

15. A Doherty power amplifier comprising:
a carrier amplifier with a carrier amplifier output terminal, wherein the carrier amplifier is configured to produce an amplified carrier output signal at the carrier amplifier output terminal;
a peaking amplifier with a peaking amplifier output terminal, wherein the peaking amplifier is configured to produce an amplified peaking output signal at the peaking amplifier output terminal;
an output combining circuit that includes
a combining node configured to combine the amplified carrier output signal with the amplified peaking output signal,
a carrier output circuit coupled between the carrier amplifier output terminal and the combining node, wherein the carrier output circuit is characterized by a first electrical length at a fundamental frequency of operation of the Doherty power amplifier, and the carrier output circuit includes
a first transmission line coupled between the carrier amplifier output terminal and the combining node, and
a harmonic termination circuit coupled between the carrier amplifier output terminal and a ground reference node, wherein the harmonic termination circuit is configured to resonate at or near a second harmonic frequency of the fundamental frequency; and
a peaking output circuit coupled between the peaking amplifier output terminal and the combining node, wherein the peaking output circuit is characterized by a second electrical length at the fundamental frequency of operation, and the peaking output circuit includes
a second transmission line and a third transmission line coupled in series between the peaking amplifier output terminal and the combining node, with a first intermediate node between the second and third transmission lines, and
a first capacitor with a first terminal coupled to the first intermediate node and a second terminal coupled to the ground reference node.

16. The Doherty power amplifier of claim 15, wherein the carrier output circuit further comprises:
a first inductive element coupled between the carrier amplifier output terminal and a second intermediate node.

17. The Doherty power amplifier of claim 16, wherein the harmonic termination circuit comprises:
a second inductive element and a second capacitor coupled in series between the second intermediate node and the ground reference node.

18. The Doherty power amplifier of claim 17, further comprising:
a first shunt inductor-capacitor circuit that includes a third inductive element and a third capacitor coupled in series between the second intermediate node and the ground reference node, wherein a third intermediate node between the third inductive element and the third capacitor corresponds to a first radio frequency (RF) cold point, and the third intermediate node is connected to a carrier drain bias voltage terminal; and
a second shunt inductor-capacitor circuit that includes a fourth inductive element and a fourth capacitor coupled in series between the peaking amplifier output terminal and the ground reference node, wherein a fourth intermediate node between the fourth inductive element and the fourth capacitor corresponds to a second RF cold point, and the fourth intermediate node is connected to a peaking drain bias voltage terminal.

19. The Doherty power amplifier of claim 15, wherein:
the carrier amplifier die includes a first power transistor with a first gate terminal, a first drain terminal, and a first source terminal, wherein the first gate terminal corresponds to a carrier amplifier input terminal, and the first drain terminal corresponds to the carrier amplifier output terminal;
the carrier amplifier die is characterized by a first drain-source capacitance between the first drain terminal and the first source terminal;
the carrier output circuit, including an effect the first drain-source capacitance, is characterized by a first electrical length in a range of 60 degrees to 90 degrees at the fundamental frequency;
the peaking amplifier die includes a second power transistor with a second gate terminal, a second drain terminal, and a second source terminal, wherein the second gate terminal corresponds to a peaking amplifier input terminal, and the second drain terminal corresponds to the peaking amplifier output terminal;
the peaking amplifier is characterized by a second drain-source capacitance between the second drain terminal and the second source terminal; and
the peaking output circuit, including an effect of the second drain-source capacitance, is characterized by a second electrical length in a range of 140 degrees to 180 degrees at the fundamental frequency.

20. The Doherty power amplifier of claim 19, wherein the plurality of terminals further includes a radio frequency (RF) input, and the amplifier module further comprises:
a power splitter connected to the module substrate with a power splitter input, a first power splitter output, and a second power splitter output, wherein the power splitter input is coupled to the RF input and is configured to receive an input RF signal, the power splitter is configured to split a power of the input RF signal into a carrier input signal that is provided at the first power splitter output and a peaking input signal that is provided at the second power splitter output;
a carrier input circuit connected to the module substrate and coupled between the first power splitter output and the carrier amplifier input terminal, wherein the carrier input circuit is characterized by a third electrical length at the fundamental frequency; and
a peaking input circuit connected to the module substrate and coupled between the second power splitter output and the peaking amplifier input terminal, wherein the peaking input circuit is characterized by a fourth electrical length at the fundamental frequency, and
wherein the first electrical length plus the third electrical length is equal to the second electrical length plus the fourth electrical length at the fundamental frequency.
